(19) United States
(12) Patent Application Publication
(10) Pub. No.: US 2021/0118726 A1
(43) Pub. Date: Apr. 22, 2021

(54) METHOD FOR TRANSFERRING THIN FILM

(71) Applicant: Shenyang Silicon Technology Co., Ltd., Shenyang (CN)

(72) Inventors: Qing GAN, Shenyang (CN); Jie LI, Shenyang (CN)

(73) Assignee: Shenyang Silicon Technology Co., Ltd., Shenyang (CN)

(21) Appl. No.: 16/879,970

(22) Filed: May 21, 2020

(30) Foreign Application Priority Data
Oct. 17, 2019 (CN) 201910986159.8

(51) Int. Cl. H01L 21/762

(52) U.S. Cl. CPC H01L 21/76254

(57) ABSTRACT

A method for transferring a thin film. The method includes: providing a supply substrate; performing ion implantation process to form an ion layer at the defined depth in the supply substrate, the ion depth defining a thin layer in the supply substrate: a thin film, which is a defined portion of the supply substrate by implanted ions, and a remnant substrate, which is a remaining portion of the supply substrate without the thin film; and performing a direct wafer bonding process to join a handle substrate onto the supply substrate. The method for transferring the thin film can improve wafer bonding; a larger wafer is transferred to the handle wafer with a uniform thin layer thickness and a larger surface roughness, and the bonded wafer can be treated from 100° C. to 450° C. to achieve different service lives.

### FIELD

The present invention relates to the field of wafer technology, and more particularly, to a method for transferring a thin film.

### BACKGROUND

In addition to traditional food heating, many novel applications of multimode microwave cavity bodies for material heating have been found, such as microwave-enhanced chemical reactions, ceramic sintering, and polymer curing for semiconductor packaging.

It is proposed to transfer a thin Si layer to a handle wafer by using a fixed frequency (2.45 MHz, 900 MHz or 2.45 GHz) or 2.45 MHz-900 MHz variable frequency microwaves (referring to U.S. Pat. No. 6,486,008 and China Patent ZL2003 10123080.1). However, due to uneven heating (see FIG. 1), the transferred thin layer has many problems, such as an irregular ring pattern, obvious roughness variation on a split surface, or even a small non-transferred area, especially for wafers having diameters larger than 200 mm (see FIG. 2). Even with the rotation of a stage, the microwave multimode cavity of a fixed frequency still has a larger ring near or at the edge of the wafer (see FIG. 3).

### SUMMARY

Aiming at the deficiencies of the prior art, the present invention provides a method for transferring a thin film, and solves the problem of the poor transferring quality of the existing thin layer.

In order to solve the above object, the present invention is implemented with the following technical solution. A method for transferring a thin film comprises: providing a supply substrate; performing ion implantation process to form an ion layer at the defined depth in the supply substrate, the ion depth defining a thin layer in the supply substrate: a thin film, which is a defined portion of the supply substrate by implanted ions, and a remnant substrate, which is a remaining portion of the supply substrate without the thin film; performing a direct wafer bonding process to join a handle substrate onto the supply substrate, forming a bonded substrate pair; and separating the thin film from the remnant substrate by using variable frequency microwave irradiation, the thin film transferring from the supply substrate to the surface of the handle substrate.

Preferably, the method further comprises a pre-heat process performed after the formation of the ion separation layer and before the thin film separation from the supply substrate, wherein the pre-heat process is configured to polymerize the implanted ions and to generate crystal fractures; and the polymerized ions form bubbles within the supply substrate.

Preferably, the pre-heat process is performed by variable frequency microwave irradiation or thermal treatment.

Preferably, the ion implantation process is a standard ion implantation process, which is performed at a different temperature for each treatment step.

Preferably, the ions used in the ion implantation process comprise hydrogen ions, oxygen ions, nitrogen ions, fluorine ions, chloride ions, helium ions or neon ions.

Preferably, the ions used in the ion implantation process are ions or molecular ions.

Preferably, the wafer bonding process is a direct bonding process, which is performed at a low temperature, in a vacuum or on a bonding surface enhanced by plasma treatment.

Preferably, the microwave irradiation is applied by a variable frequency microwave generating device, and the variable frequency microwave generating device increases the kinetic energy of the implanted ions, the molecular ions or reactants generated by the reactions between the ions and the substrates in a bonded structure.

Preferably, the variable frequency microwave irradiation is capable of being combined with direct thermal heating of the bonded structure, wherein the temperature in the direct heating is at most 450° C.

Preferably, the kinetic energy of the implanted ions, the molecular ions or the reactants generated by the reaction between the ions and the substrate in the bonded structure is increased by direct excitation but not by thermally heating the bonded structure.

Preferably, the variable frequency microwave generating device is configured to generate a high frequency alternating electromagnetic field, and variable frequency microwaves are generated by frequency sweeping between 2 GHz and 24 GHz.

Preferably, the variable frequency microwave generating device generates a high frequency alternating electromagnetic field, and the variable frequency microwaves are generated by frequency sweeping between 4 GHz and 12 GHz.

Preferably, the variable frequency microwave generating device is configured to generate a high frequency alternating electromagnetic field, and the variable frequency microwaves are generated by frequency sweeping between 5 GHz and 7 GHz.

Preferably, the variable frequency microwave generating device is configured to generate a high frequency alternating electromagnetic field, and the variable frequency microwaves are generated by frequency sweeping between 5.85 GHz and 6.65 GHz.

Preferably, the variable frequency microwaves are generated by frequency sweeping at 0.1 sec cycle time between each frequency.

Preferably, the bonded structure is exposed to microwave irradiation for more than 1 minute.

The present invention provides a method for transferring a thin film, and has the following beneficial effects. The method for transferring the thin film can improve wafer bonding, a larger wafer is transferred to the handle wafer with a uniform thin layer thickness and a larger surface roughness, and the bonded wafer can be treated from 100° C. to 450° C. to achieve different service lives. By the lower power with the maximum value of 1 kW, in an initial step, the bonding strength can be improved, and the problem of relatively poor thin film transferring effect in the prior art is solved.

### BRIEF DESCRIPTION OF THE DRAWINGS

FIG. 1 shows fixed frequency microwave heating where (a) is a single frequency diagram in a microwave multimode cavity; (b) is a 3-D model of heating nodes; and (c) is an actual result showing hot spots and arcing.

FIG. 2 shows thin film transferring of Si of 200 mm by 2.45 GHz microwave irradiation where (a) shows circular fringes on a transferred surface and (b) shows a surface roughness between regions separated by the stripes observed under an optical microscope.

FIG. 3 shows a very uniform heating field achieved by a fixed frequency microwave multimode cavity with a turntable, but a circularly symmetrical non-uniform heating pattern still exists where (A) and (B) show two heating patterns generated on thermal paper by two different 2.45 GHz domestic microwave ovens having the same disk-like load.

FIG. 4 shows the multimode cavity heating of the variable frequency microwaves, where (a) is a variable frequency microwave diagram of 4100 frequencies having a sweeping rate of 0.1 sec and a dwell time of 25 μs in the microwave multimode cavity; (b) shows a 3-D model of the heating nodes; and (c) is an actual result showing no hot spots and arcing; the variable frequency microwaves have an inherent advantage compared with fixed frequency microwaves by sweeping the frequency in a frequency band to achieve much better heating uniformity; the variable frequency microwaves have been used in semiconductor assembly processes such as polymer curing and ceramic sintering. In the present invention, the variable frequency microwaves will be used in wafer bonding and thin layer splitting from a large wafer (>=200 mm dia.).

FIG. 5 is a process flowchart of a wafer.

### DETAILED DESCRIPTION

The technical solutions in the embodiments of the present invention will be clearly and completely described below in conjunction with the accompanying drawings in the embodiments of the present invention. It is obvious that the described embodiments are only part but not all of the embodiments of the present invention. All other embodiments obtained by those skilled in the art without creative efforts based on the embodiments in the present invention are within the protection scope of the present invention.

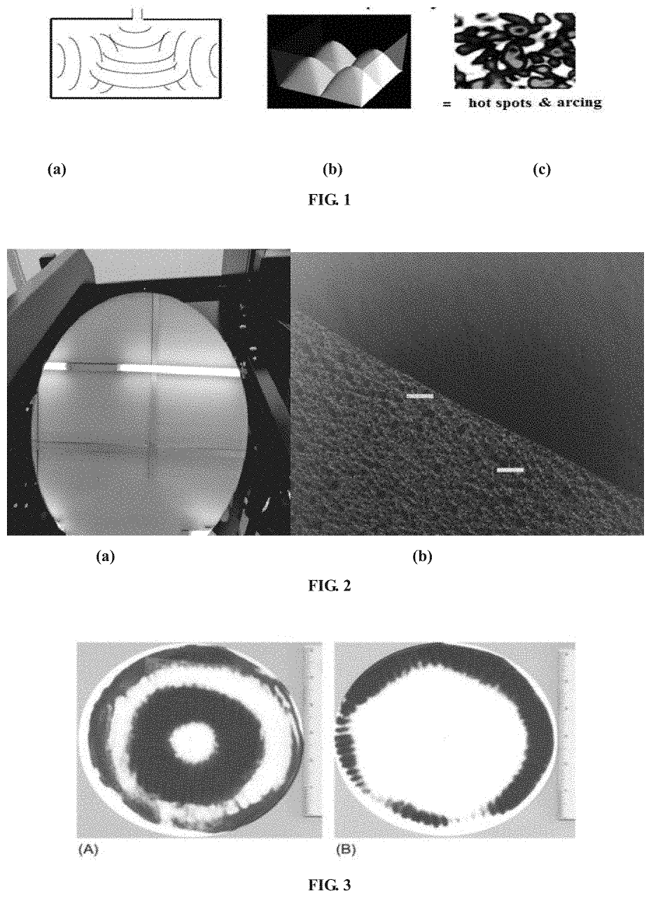

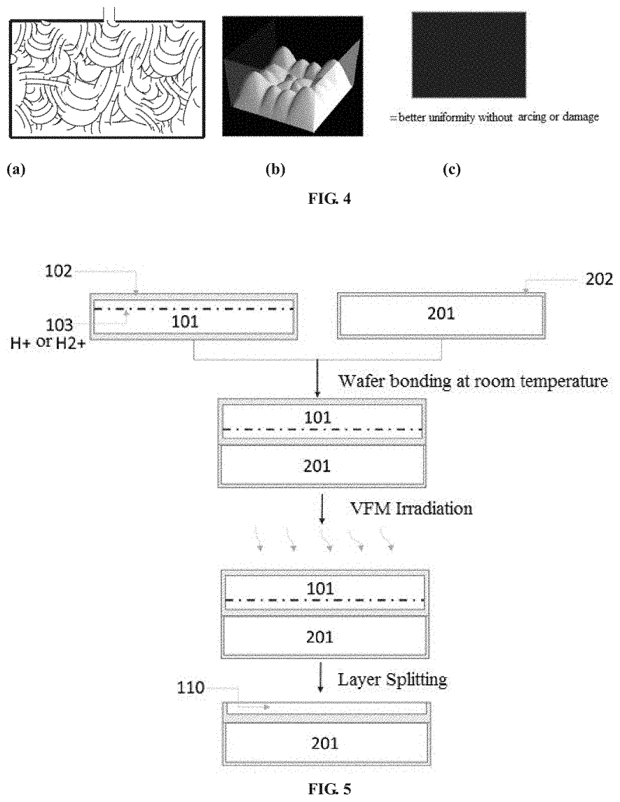

Referring to FIGS. 1-3, the present invention provides a technical solution as follows. A method for transferring a thin film is characterized by comprising: providing a supply substrate; performing ion implantation process to form an ion layer at the defined depth in the supply substrate, the ion depth defining a thin layer in the supply substrate: a thin film, which is a defined portion of the supply substrate by implanted ions, and a remnant substrate, which is a remaining portion of the supply substrate without the thin film; performing a direct wafer bonding process to join a handle substrate onto the supply substrate, forming a bonded substrate pair; and separating the thin film from the remnant substrate by using variable frequency microwave irradiation, and transferring the thin film from the supply substrate to the surface of the handle substrate. The method further comprises a pre-heat process performed after the formation of the ion separation layer and before the thin film separation from the supply substrate, wherein the pre-heat process is configured to polymerize the implanted ions and to generate crystal fractures, and the polymerized ions form bubbles within the supply substrate. The pre-heat process is performed by variable frequency microwave irradiation or thermal treatment. The ion implantation process is a standard ion implantation process, which is performed at a different temperature for each treatment step. The ions used in the ion implantation process comprise hydrogen ions, oxygen ions, nitrogen ions, fluorine ions, chloride ions, helium ions or neon ions. The ions used in the ion implantation process are ions or molecular ions. The wafer bonding process is a direct bonding process, which is performed at a low temperature, in a vacuum or on a bonding surface enhanced by plasma treatment. The microwave irradiation is applied by a variable frequency microwave generating device, and the variable frequency microwave generating device increases the kinetic energy of the implanted ions, the molecular ions or the reactants generated by the reactions between the ions and the substrates in the bonded structure. The variable frequency microwave irradiation is capable of being combined with direct thermal heating of the bonded structure, and the direct heating is at most 450° C. The kinetic energy of the implanted ions, the molecular ions or the reactant generated by the reaction between the ions and the substrates in the bonded structure is increased by direct excitation but not by thermally heating the bonded structure. The variable frequency microwave generating device is configured to generate a high frequency alternating electromagnetic field, and the variable frequency microwaves are generated by frequency sweeping between 2 GHz and 24 GHz. The variable frequency microwave generating device generates a high frequency alternating electromagnetic field, and the variable frequency microwaves are generated by frequency sweeping between 4 GHz and 12 GHz. The variable frequency microwave generating device is configured to generate a high frequency alternating electromagnetic field, and the variable frequency microwaves are generated by frequency sweeping between 5 GHz and 7 GHz. The variable frequency microwave generating device is configured to generate a high frequency alternating electromagnetic field, and the variable frequency microwaves are generated by frequency sweeping between 5.85 GHz and 6.65 GHz. The variable frequency microwaves are generated by frequency sweeping at 0.1 sec cycle time between each frequency. The bonded structure is exposed to microwave irradiation for more than 1 min.

A person skilled in the art uses wires to connect all electrical components in the solution to a power supply adapted to the all electrical components; and an appropriate controller is selected according to an actual situation to meet control requirements. The specific connecting and control sequence may refer to the following working principle, in which the respective electrical components are electrically connected in sequence based on a work order of the electrical components. The detailed connection means of the electrical components is well known in the art. The following mainly introduces the working principle and the process, and does not describe the electrical control any more.

Embodiments: in the present invention, the new variable frequency microwaves (VFM) of 2 GHz-18 GHz are used to improve wafer bonding. For larger wafers (with diameters>200 mm), the thin layer is transferred to the handle wafer with a uniform thin layer thickness and a larger surface roughness. FIG. 5 is a process flowchart with the following treatment steps.

1) The supply substrate 101 has an implantation layer 103, and the implanted ions may be hydrogen ions and/or helium ions. Optionally, the supply substrate 101 is covered with a dielectric layer 102, which may be an oxide, nitride or oxynitride layer. The supply substrate 101 may be a semiconductor of Si, Ge, SiC, SiGe, III-V or II-VI, etc. The handle substrate 201 may be a semiconductor, glass, Al₂O₃, AlN, BeO or even ceramic.

Optionally, the substrate 201 is covered with a dielectric layer 202, which may be an oxide, nitride or oxynitride layer.

2) The substrates 101 and 201 are joined by direct bonding at room temperature. The wafer can be cleaned with a wet chemical (for example, RCA1, RCA2, and/or a dilute HF solution) before bonding. The wafer surface can further be activated by O2, N2, Ar or NH3 plasma to promote direct bonding.

3) Optionally, the bonding pair 101/201 may be subjected to thermal treatment at the temperatures from 100° C. up to 450° C. for various periods of time.

4) The bonding pair 101/201 is then treated by VFM irradiation. The VFM can sweep in the frequency band from 2 GHz to 18 GHz with the maximum power of 2 kW.

The VFM treatment may be a single treatment condition or multiple steps. In the last embodiment, the initial step is of a relatively low power up to 1 kW, so as to increase the bonding strength. The single step or the subsequent multiple steps is to activate the implanted H or He ions to form a thin layer of gas molecules and split the thin layer 110 from the substrate 101 onto the substrate 201.

It is to be understood that the term “includes”, “containing” or any other variants thereof is intended to cover non-exclusive including, such that the process, method, article, or device including a plurality of elements includes not only those elements but also other elements that are not explicitly listed, or also includes the elements that are inherent to such a process, method, item, or device. Without more limitations, the element defined by the phrase “including a . . . ” does not exclude the presence of additional equivalent elements in the process, method, item, or device that includes the element.

The foregoing is only the preferred embodiments of the present disclosure, and is not intended to limit the present disclosure. Various changes and modifications may be made to the present disclosure for those skilled in the art. Any modifications, equivalent substitutions, improvements, etc., made within the spirit and principles of the present disclosure should be included within the scope of the present disclosure.

1. A method for transferring a thin film, comprising:
providing a supply substrate;
performing ion implantation treatment to form an ion layer at a specified depth in the supply substrate, wherein the ion depth defines a thin layer in the supply substrate,
a thin film is a part defined on the supply substrate by implanted ions, and
a remaining substrate is a remaining part of the supply substrate without the thin film;
performing direct wafer bonding treatment to bond a processing substrate to the supply substrate to form a bonded substrate pair; and
separating the thin film from the remaining substrate by using variable frequency microwave radiation, and transferring the thin film from the supply substrate to the surface of the processing substrate.

2. The method for transferring the thin film according to claim 1, further comprising a preheating process performed after forming an ion separation layer and before separating the thin film from the supply substrate, wherein the preheating process is configured to polymerize the implanted ions and to generate a crystal flaw, and the polymerized ions form bubbles within the supply substrate.

3. The method for transferring the thin film according to claim 2, wherein the preheating process is performed by variable frequency microwave radiation or heat treatment.

4. The method for transferring the thin film according to claim 1, wherein the ion implantation treatment is standard ion implantation treatment, which is performed at a different temperature for each treatment step.

5. The method for transferring the thin film according to claim 1, wherein the ions used in the ion implantation treatment comprise hydrogen ions, oxygen ions, nitrogen ions, fluorine ions, chloride ions, helium ions or neon ions.

6. The method for transferring the thin film according to claim 1, wherein the ions used in the ion implantation treatment are ions or molecular ions.

7. The method for transferring the thin film according to claim 1, wherein the wafer bonding treatment is direct bonding treatment, which is performed at low temperature, in vacuum or on a bonding surface enhanced by plasma treatment.

8. The method for transferring the thin film according to claim 1, wherein the microwave radiation is applied by a variable frequency microwave generating device, and the variable frequency microwave generating device increases kinetic energy of the implanted ions, the molecular ions or a reactant generated by the reaction between the ions and the substrates in a bonding structure.

9. The method for transferring the thin film according to claim 1, wherein the variable frequency microwave radiation is capable of being combined with direct thermal heating of the bonding structure, the direct heating being at most 450° C.

10. The method for transferring the thin film according to claim 8, wherein the kinetic energy of the implanted ions, the molecular ions or the reactant generated by the reaction between the ions and the substrate in the bonding structure is increased by direct excitation instead of thermally heating the bonding structure.

11. The method for transferring the thin film according to claim 8, wherein the variable frequency microwave generating device is configured to generate a high frequency alternating electromagnetic field, and variable frequency microwaves are generated by frequency scanning between 2 GHz and 24 GHz.

12. The method for transferring the thin film according to claim 8, wherein the variable frequency microwave generating device generates a high frequency alternating electromagnetic field, and the variable frequency microwaves are generated by frequency scanning between 4 GHz and 12 GHz.

13. The method for transferring the thin film according to claim 8, wherein the variable frequency microwave generating device is configured to generate a high frequency alternating electromagnetic field, and the variable frequency microwaves are generated by frequency scanning between 5 GHz and 7 GHz.

14. The method for transferring the thin film according to claim 8, wherein the variable frequency microwave generating device is configured to generate a high frequency alternating electromagnetic field, and the variable frequency microwaves are generated by frequency scanning between 5.85 GHz and 6.65 GHz.

15. The method for transferring the thin film according to claim 8, wherein the variable frequency microwaves are generated by performing frequency scanning between all frequencies with the cycle time of 0.1 s.

16. The method for transferring the thin film according to claim 8, wherein the bonding structure is exposed to microwave radiation for more than 1 min.
